(19) United States
(12) Patent Application Publication
(10) Pub. No.: US 2024/0227115 A1
(43) Pub. Date: Jul. 11, 2024

(54) POLISHING APPARATUS

(71) Applicant: EBARA CORPORATION, Tokyo (JP)

(72) Inventors: Tetsuya TERADA, Tokyo (JP); Hiroshi SOTOZAKI, Tokyo (JP); Takuya MORIURA, Tokyo (JP)

(21) Appl. No.: 17/996,952

(22) PCT Filed: May 19, 2022
(86) PCT No.: PCT/JP2022/020822

§ 371 Date: Oct. 24, 2022

(30) Foreign Application Priority Data
Jun. 11, 2021 (JP) 2021-098177
Jun. 11, 2021 (JP) 2021-098188

(51) Int. Cl. B24B 37/04; B24B 57/02

(52) U.S. Cl. CPC B24B 37/04; B24B 57/02

(57) ABSTRACT

When a polishing liquid is supplied while moving a polishing liquid supply head including a plurality of polishing liquid supply ports above a polishing pad, a uniformity of a polishing liquid supply range is improved. A polishing apparatus 1 includes a polishing table for supporting a polishing pad 100, a polishing head 30 for holding an object, and a polishing liquid supply device 40 for supplying a polishing liquid between the polishing pad 100 and the object. The polishing liquid supply device 40 includes a polishing liquid supply head 41 including a plurality of polishing liquid supply ports 414, a link mechanism 60 configured to move the polishing liquid supply head 41 along a polishing surface of the polishing pad 100, and a drive mechanism 90 configured to drive the link mechanism 60. The drive mechanism 90 is configured to drive the link mechanism 60 such that the plurality of polishing liquid supply ports 414 are arranged along a radial direction of the polishing pad 100 in a first state 450 where the polishing liquid supply head 41 is disposed to be opposed to a center side of the polishing pad 100 and the plurality of polishing liquid supply ports 414 are arranged along a radial direction of the polishing pad 100 in a second state 460 where the polishing liquid supply head 41 is disposed to be opposed to an outer edge side of the polishing pad 100 compared with the first state 450.

### TECHNICAL FIELD

This application relates to a polishing apparatus.

### BACKGROUND ART

In a manufacturing process of a semiconductor device, a planarization technique of a semiconductor device surface has become increasingly important. As the planarization technique, Chemical Mechanical Polishing (CMP) has been known. In the chemical mechanical polishing, a substrate such as a semiconductor wafer is brought into sliding contact with a polishing pad while a polishing liquid (slurry) containing abrasive grains of, for example, silica (SiO₂) and/or ceria (CeO₂) is supplied to the polishing pad by using a polishing apparatus, thereby performing polishing.

A polishing apparatus that performs the CMP process includes a polishing table for supporting a polishing pad, a polishing head for holding an object such as a substrate, and a polishing liquid supply device for supplying a polishing liquid between the polishing pad and the substrate. The polishing apparatus supplies the polishing liquid from the polishing liquid supply device to the polishing pad, presses the substrate against a surface (polishing surface) of the polishing pad with a predetermined pressure, and rotates the polishing table and the polishing head, thereby polishing the surface of the substrate to be flat.

PTL 1 discloses a polishing liquid supply device for supplying a polishing liquid to a polishing pad. The polishing liquid supply device includes a plurality of arms coupled by a plurality of hinge coupling joints, and is configured to supply a polishing liquid via nozzles disposed at distal ends of the arms. Since the plurality of arms coupled by the hinge coupling joints can be moved with respective desired degrees of freedom, the polishing liquid supply device can supply the polishing liquid to a desired region on the polishing pad.

PTL 2 discloses a polishing liquid supply device for supplying a polishing liquid to a polishing pad. The polishing liquid supply device linearly drives a dispenser arm including a plurality of nozzles arranged along a radial direction of a polishing pad, thereby allowing supplying a polishing liquid to a larger area of the polishing pad.

### CITATION LIST

### Patent Literature

PTL 1: Japanese Unexamined Patent Application Publication (Translation of PCT Application) No. 2011-530422
PTL 2: Japanese Unexamined Patent Application Publication (Translation of PCT Application) No. 2011-530422

### SUMMARY OF INVENTION

### Technical Problem

However, in the prior art such as PTL 1, it is not considered to improve a uniformity of a polishing liquid supply range when the polishing liquid is supplied while moving a polishing liquid supply head including a plurality of polishing liquid supply ports above a polishing pad.

That is, a common polishing liquid supply device supplies a polishing liquid while moving a polishing liquid supply head above a polishing pad by turning an arm holding the polishing liquid supply head above a polishing table. In this case, for example, since a plurality of polishing liquid supply ports of the polishing liquid supply head are arranged in a radial direction of the polishing pad in the center side of the polishing pad, a polishing liquid supply range is wide. In contrast, when the polishing liquid supply head is moved to an outer edge side of the polishing pad by turning the arm, since the arrangement direction of the plurality of polishing liquid supply ports shifts from the radial direction to a circumferential direction of the polishing pad, the polishing liquid supply range is narrowed.

In this respect, while the polishing liquid supply device disclosed in PTL 1 is configured to move the plurality of arms coupled by the plurality of hinge coupling joints by desired degrees of freedom, it is not considered to improve the uniformity of the polishing liquid supply range.

Therefore, it is one object of the present invention to improve a uniformity of a polishing liquid supply range when the polishing liquid is supplied while moving a polishing liquid supply head including a plurality of polishing liquid supply ports above a polishing pad.

In the prior art such as PTL 2, there is a room for improvement in enhancing the uniformity of the polishing liquid supply range to the polishing pad and suppressing an occurrence of a defect on the substrate caused by the polishing liquid bouncing from the polishing pad.

That is, a common polishing liquid supply device holds a polishing liquid supply head including a plurality of polishing liquid supply ports by an arm, and supplies a polishing liquid while moving the polishing liquid supply head above a polishing pad by turning the arm above a polishing table. In this case, for example, since the plurality of polishing liquid supply ports of the polishing liquid supply head are arranged in a radial direction of the polishing pad in the center side of the polishing pad, a polishing liquid supply range is wide. In contrast, when the polishing liquid supply head is moved to an outer edge side of the polishing pad by turning the arm, since the arrangement direction of the plurality of polishing liquid supply ports shifts from the radial direction to a circumferential direction of the polishing pad, the polishing liquid supply range is narrowed.

In this respect, while the technique disclosed in PTL 2 linearly drives the polishing liquid supply head in the radial direction of the polishing pad, the polishing liquid bouncing from the polishing pad is not considered. That is, in the technique disclosed in PTL 2, since the polishing liquid supply head and the arm are disposed at the same height, the polishing liquid that is supplied from the polishing liquid supply head and collides against a polishing surface of the polishing pad to be spattered on the polishing pad easily adheres to the arm. When the polishing liquid adheres to the arm, the polishing liquid adhered to the arm dries and becomes dust, and then falls onto the polishing pad in some cases, thus possibly resulting in the occurrence of the defect, such as a scratch, on the substrate.

Therefore, it is one object of the present invention to enhance a uniformity of a polishing liquid supply range to a polishing pad and to suppress an occurrence of a defect on a substrate caused by the polishing liquid bouncing from the polishing pad.

### Solution to Problem

According to one embodiment, a polishing apparatus is disclosed, and the polishing apparatus includes: a table for supporting a polishing pad; a polishing head for holding an object: and a polishing liquid supply device for supplying a polishing liquid between the polishing pad and the object. The polishing apparatus polishes the object by bringing the polishing pad into contact with the object in a presence of a polishing liquid and rotationally moving the polishing pad and the object with respect to one another. The polishing liquid supply device includes a polishing liquid supply head including a plurality of polishing liquid supply ports, a link mechanism configured to move the polishing liquid supply head along a polishing surface of the polishing pad, and a drive mechanism configured to drive the link mechanism. The drive mechanism is configured to drive the link mechanism such that the plurality of polishing liquid supply ports are arranged along a radial direction of the polishing pad in a first state where the polishing liquid supply head is disposed to be opposed to a center side of the polishing pad and the plurality of polishing liquid supply ports are arranged along a radial direction of the polishing pad in a second state where the polishing liquid supply head is disposed to be opposed to an outer edge side of the polishing pad compared with the first state.

According to one embodiment, a polishing apparatus is disclosed, and the polishing apparatus includes: a table for supporting a polishing pad; a polishing head for holding an object: and a polishing liquid supply device for supplying a polishing liquid between the polishing pad and the object. The polishing apparatus polishes the object by bringing the polishing pad into contact with the object in a presence of a polishing liquid and rotationally moving the polishing pad and the object with respect to one another. The polishing liquid supply device includes a polishing liquid supply head including a plurality of polishing liquid supply ports, an arm that extends along a polishing surface of the polishing pad at a position higher than the polishing liquid supply head and is configured to hold the polishing liquid supply head, and a linear motion drive mechanism configured to linearly move the polishing liquid supply head between a center side and an outer edge side of the polishing pad along a radial direction of the polishing pad in a state where the plurality of polishing liquid supply ports are arranged to be opposed to the polishing pad along the radial direction of the polishing pad.

### BRIEF DESCRIPTION OF DRAWINGS

FIG. 1 is a perspective view illustrating a schematic configuration of a polishing apparatus according to one embodiment.

FIG. 2 is a cross-sectional view schematically illustrating a configuration of a polishing liquid supply head.

FIG. 3 is a top view illustrating a schematic configuration of a polishing apparatus according to one embodiment.

FIG. 4 is a top view illustrating a schematic configuration of a polishing apparatus according to a comparative example.

FIG. 5A is a side view illustrating a schematic configuration of an atomizer according to one embodiment, and illustrates a state of the atomizer when supplying a cleaning fluid.

FIG. 5B is a side view illustrating the schematic configuration of the atomizer according to the one embodiment, and illustrates a state of the atomizer when not supplying a cleaning fluid.

FIG. 6A is a bottom view illustrating a schematic configuration of an atomizer according to one embodiment.

FIG. 6B is a cross-sectional view of the atomizer taken along a line B-B of FIG. 6A.

FIG. 7A is a cross-sectional view illustrating a schematic configuration of an atomizer according to a modification.

FIG. 7B is a cross-sectional view illustrating the schematic configuration of the atomizer according to the modification.

FIG. 8 is a perspective view illustrating a schematic configuration of a polishing apparatus according to one embodiment.

FIG. 9A is a perspective view illustrating a schematic configuration of a polishing liquid supply device according to one embodiment, and illustrates a state where an arm is stretched.

FIG. 9B is a side view illustrating the schematic configuration of the polishing liquid supply device according to the one embodiment, and illustrates the state where the arm is stretched.

FIG. 9C is a perspective view illustrating the schematic configuration of the polishing liquid supply device according to the one embodiment, and illustrates a state where the arm is shrunk.

FIG. 9D is a side view illustrating the schematic configuration of the polishing liquid supply device according to the one embodiment, and illustrates the state where the arm is shrunk.

FIG. 10A is a top view illustrating a schematic configuration of a polishing apparatus according to one embodiment, and illustrates a state where a polishing liquid supply head is disposed in a center side of a polishing pad.

FIG. 10B is a top view illustrating the schematic configuration of the polishing apparatus according to the one embodiment, and illustrates a state where the polishing liquid supply head is disposed in an outer edge side of the polishing pad.

FIG. 10C is a top view illustrating the schematic configuration of the polishing apparatus according to the one embodiment, and illustrates a state where the polishing liquid supply head is disposed outside a polishing table.

### DESCRIPTION OF EMBODIMENTS

The following describes embodiments of the present invention with reference to the drawings. In the attached drawings, the same or similar reference numerals are attached to the same or similar components, and overlapping descriptions regarding the same or similar components may be omitted in the descriptions of the respective embodiments. Features illustrated in the respective embodiments are applicable to other embodiments in so far as they are consistent with one another.

In this description, a “substrate” includes any object to be processed including a magnetic recording medium, a magnetic recording sensor, a mirror, an optical element, a micro mechanical element, or a partially fabricated integrated circuit, in addition to a semiconductor substrate, a glass substrate, a liquid crystal substrate, and a printed circuit board. The substrate has any shape including a polygonal shape and a circular shape. In this description, while expressions such as “front surface,” “rear surface,” “front,” “rear,” “up,” “down,” “left,” “right,” “vertical,” and “horizontal” are used, they indicate positions and directions on the paper of the exemplary drawings for convenience of explanation, and may be different in actual arrangements, for example, when the apparatus is used.

### (Schematic Configuration of Polishing Apparatus)

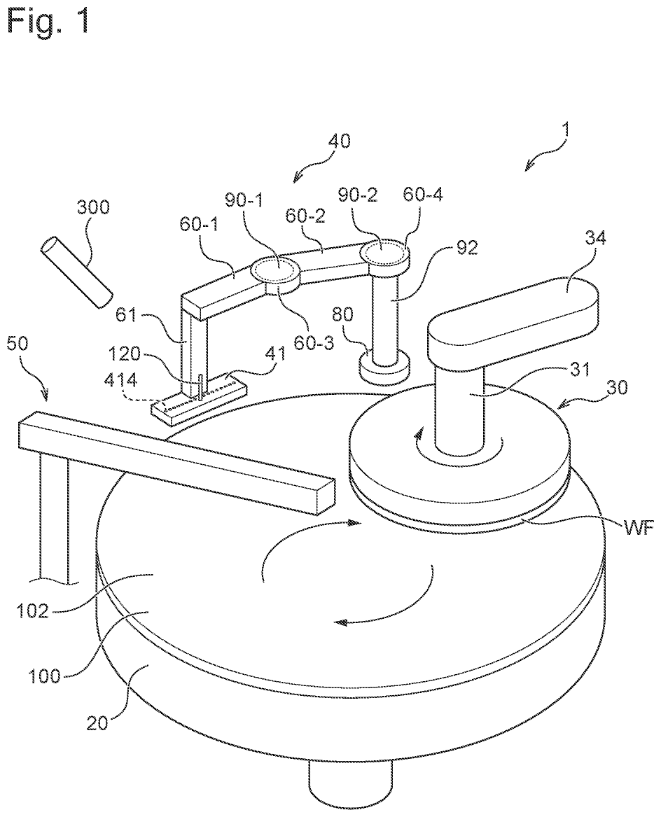

FIG. 1 is a perspective view illustrating a schematic configuration of a polishing apparatus according to one embodiment. A polishing apparatus 1 of the embodiment is configured to polish a circular plate-shaped substrate WF, such as a semiconductor wafer, as an object to be polished by using a polishing pad 100 including a polishing surface 102. As illustrated in the drawing, the polishing apparatus 1 includes a polishing table 20 for supporting the circular plate-shaped polishing pad 100, and a polishing head 30 for holding the substrate WF and pressing the substrate WF against the polishing surface 102 of the polishing pad 100. Furthermore, the polishing apparatus 1 includes a polishing liquid supply device 40 for supplying a polishing liquid (slurry) between the polishing pad 100 and the substrate WF, a cleaning mechanism 300 for supplying a cleaning liquid to the polishing liquid supply device 40 turned to an outside of the polishing pad 100, and an atomizer 50 for injecting a cleaning fluid (a liquid such as a pure water and/or a gas of nitrogen or the like) to the polishing surface 102 and washing away the already used polishing liquid, polishing residues, and the like. The polishing liquid supply device 40 is disposed in an upstream side of the rotation of the polishing pad 100 with respect to the substrate WF. While an example in which the cleaning mechanism 300 is disposed above the polishing liquid supply device 40 is illustrated in the embodiment of FIG. 1, the configuration is not limited thereto, and for example, the polishing liquid supply device 40 may be configured to be cleaned from upper and lower directions by disposing the cleaning mechanisms 300 in respective upper and lower sides of the polishing liquid supply device 40. In this description, the upstream and the downstream mean an upstream and a downstream in a case where the polishing table 20 (polishing pad 100) rotates clockwise when the polishing table 20 (polishing pad 100) is viewed from above in FIG. 1.

### (Polishing Table)

The polishing table 20 is formed in a disk shape, and configured to be rotatable having its center axis as a rotation axis line. The polishing pad 100 is attached to the polishing table 20 by adhesive bonding or the like. A surface of the polishing pad 100 forms the polishing surface 102. The polishing pad 100 is integrally rotated with the polishing table 20 by the rotation of the polishing table 20 by a motor (not illustrated).

### (Polishing Head)

The polishing head 30 holds the substrate WF on its lower surface by vacuum suction or the like. The polishing head 30 is configured to be rotatable together with the substrate by a power from a motor (not illustrated). The upper portion of the polishing head 30 is connected to a support arm 34 via a shaft 31. The polishing head 30 is movable in an up-down direction by a motor drive via an air cylinder or ball screw (not illustrated), and a distance to the polishing table 20 is adjustable. Accordingly, the polishing head 30 can press the held substrate WF against the polishing surface 102. Although not illustrated, the polishing head 30 internally includes an air bag divided into a plurality of regions, and applies a pressure to the substrate WF from a back surface by supplying a fluid pressure of any air or the like to each region of the air bag. Furthermore, the support arm 34 is configured to be turned by a motor (not illustrated), and moves the polishing head 30 in a direction parallel to the polishing surface 102. In this embodiment, the polishing head 30 is configured to be movable between a substrate receiving position (not illustrated) and an upper position of the polishing pad 100, and configured to have a changeable press position of the substrate WF to the polishing pad 100.

### (Polishing Liquid Supply Device)

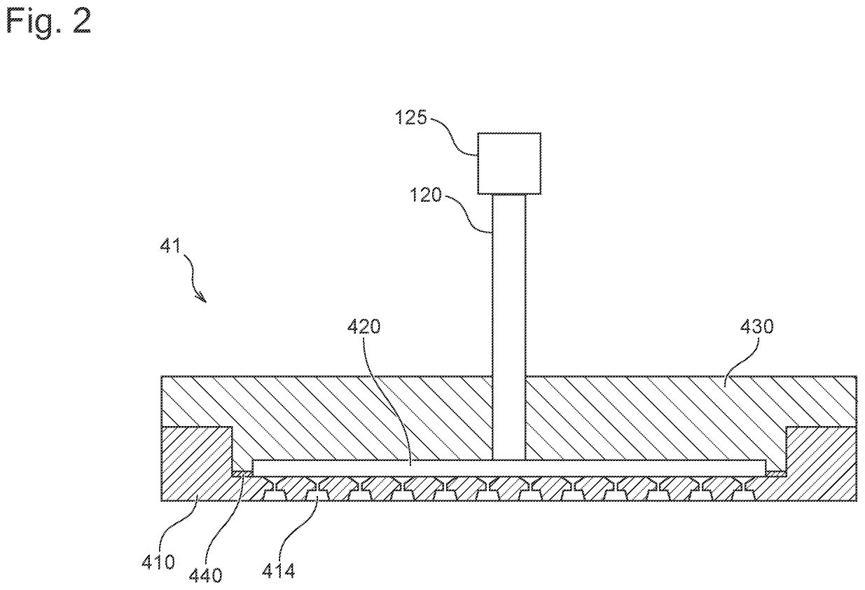

The polishing liquid supply device 40 includes a polishing liquid supply head 41 for supplying the polishing liquid to the polishing pad 100. FIG. 2 is a cross-sectional view schematically illustrating a configuration of the polishing liquid supply head. As illustrated in FIG. 2, the polishing liquid supply head 41 includes a supply member main body 410 and a cover 430 coupled to the supply member main body 410 via a packing 440. The supply member main body 410 is formed in a rectangular plate shape, and provided with a depression in the center. A plurality of polishing liquid supply ports 414 arranged along a longitudinal direction are formed in the depression portion of the supply member main body 410.

For the shape of the polishing liquid supply port 414, while the polishing liquid supply port 414 is provided to the supply member main body 410 as a hole, the shape is not limited thereto, and the polishing liquid supply port 414 may be a nozzle projecting with respect to a lower surface of the supply member main body 410. The nozzle as the polishing liquid supply port 414 more preferably has a conical shape in which an angle of a distal end is an acute angle.

The cover 430 is connected to a polishing liquid supply line 120. A buffer space 420 is formed between the cover 430 and the supply member main body 410. A base end portion of the polishing liquid supply line 120 is connected to a flow rate adjustment mechanism 125 for adjusting a flow rate of the polishing liquid supplied from the polishing liquid supply device 40. A distal end portion of the polishing liquid supply line 120 is connected to the buffer space 420. The buffer space 420 temporarily stores a polishing liquid supplied from the polishing liquid supply line 120, thereby acting to uniform a back-pressure of the polishing liquid supplied to the plurality of polishing liquid supply ports 414. Accordingly, the polishing liquid supplied from the polishing liquid supply line 120 is stored in the buffer space 420, and then dropped on the polishing pad 100 from the plurality of polishing liquid supply ports 414. The polishing liquid dropped on the polishing pad 100 is supplied to a surface to be polished of the substrate WF by the rotation of the polishing table 20.

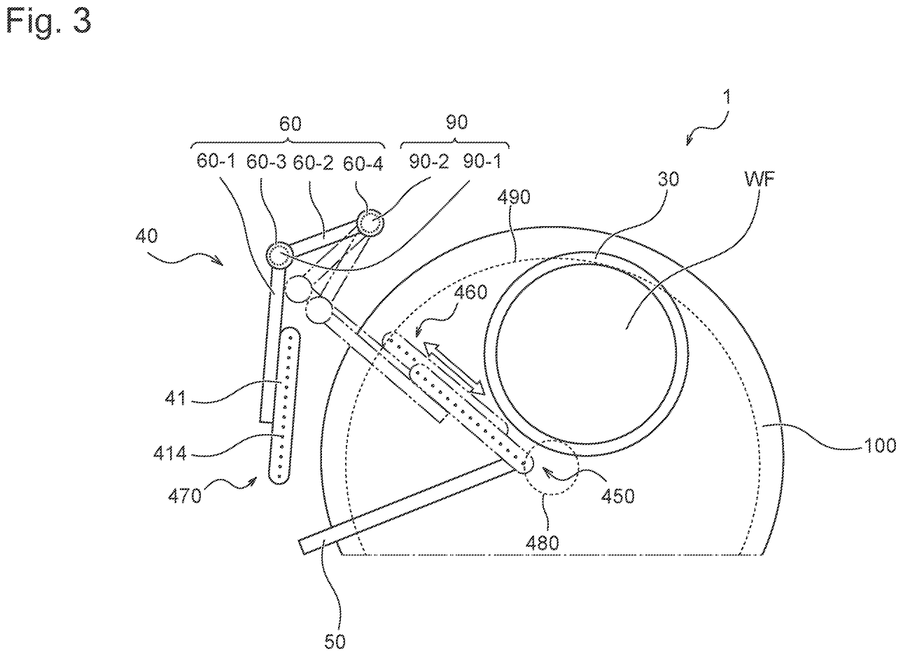

FIG. 3 is a top view illustrating a schematic configuration of a polishing apparatus according to one embodiment. As illustrated in FIG. 1 and FIG. 3, the polishing liquid supply device 40 includes the polishing liquid supply head 41, a link mechanism 60 configured to move the polishing liquid supply head 41 along the polishing surface 102 of the polishing pad 100, and a drive mechanism 90 configured to drive the link mechanism 60.

The link mechanism 60 includes a first arm 60-1 configured to hold the polishing liquid supply head 41 via a connecting member 61 extending from the polishing liquid supply head 41 in the vertical direction, and a second arm 60-2 coupled to the first arm 60-1. The first arm 60-1 and the second arm 60-2 extend in the horizontal direction. The polishing liquid supply device 40 is disposed adjacent to the polishing table 20, and includes a shaft 92 extending in the vertical direction. The link mechanism 60 includes a first coupling member (first joint) 60-3 rotatably coupling the first arm 60-1 to the second arm 60-2, and a second coupling member (second joint) 60-4 rotatably coupling the second arm 60-2 to the shaft 92. The first coupling member 60-3 and the second coupling member 60-4 are both disposed outside the polishing table 20. The polishing liquid supply device 40 includes an elevating mechanism 80 configured to collectively move up and down the polishing liquid supply head 41, the link mechanism 60, and the drive mechanism 90. The elevating mechanism 80 can be achieved by a known mechanism, such as a motor. While an example in which the link mechanism 60 includes two arms and two coupling members is indicated in this embodiment, the configuration is not limited thereto, and various kinds of link mechanisms configured to move the polishing liquid supply head 41 along the polishing surface 102 of the polishing pad 100 can be used.

The drive mechanism 90 includes a first rotation mechanism 90-1 for rotating the first arm 60-1 about the first coupling member 60-3 so as to turn the polishing liquid supply head 41 along the polishing surface 102 of the polishing pad 100. The drive mechanism 90 includes a second rotation mechanism 90-2 for rotating the second arm 60-2 about the second coupling member 60-4 so as to turn the first arm 60-1. The first rotation mechanism 90-1 and the second rotation mechanism 90-2 can be achieved by a known mechanism, such as a motor. The first rotation mechanism 90-1 and the second rotation mechanism 90-2 are configured to rotate the first arm 60-1 and the second arm 60-2 such that the polishing liquid supply head 41 moves in the horizontal direction along the polishing surface 102 of the polishing pad 100. The first rotation mechanism 90-1 and the second rotation mechanism 90-2 dispose the polishing liquid supply head 41 above the polishing pad 100 when a polishing process is performed, and retreat the polishing liquid supply head 41 to the outside of the polishing table 20 when the polishing process ends.

In this embodiment, the first rotation mechanism 90-1 and the second rotation mechanism 90-2 are configured to rotate the first arm 60-1 and the second arm 60-2 such that the plurality of polishing liquid supply ports 414 of the polishing liquid supply head 41 are always arranged along a radial direction of the polishing pad 100 when the polishing liquid is supplied to the polishing pad 100. In this description, the radial direction of the polishing pad 100 not only strictly means the radial direction of the polishing pad 100, but an angle in a range of 10° is also assumed as the radial direction.

Specifically, as illustrated in FIG. 3, the first rotation mechanism 90-1 and the second rotation mechanism 90-2 are configured to rotate the first arm 60-1 and the second arm 60-2 such that the polishing liquid supply head 41 moves between a first state 450 where the polishing liquid supply head 41 is disposed to be opposed to the center side of the polishing pad 100, a second state 460 where the polishing liquid supply head 41 is disposed to be opposed to the outer edge side of the polishing pad 100 compared with the first state 450, and a third state 470 where the polishing liquid supply head 41 is disposed outside the polishing table 20. As illustrated in FIG. 3, the drive mechanism 90 is configured to rotate the first arm 60-1 and the second arm 60-2 such that the plurality of polishing liquid supply ports 414 are arranged along the radial direction of the polishing pad 100 in the first state 450. The drive mechanism 90 is configured to rotate the first arm 60-1 and the second arm 60-2 such that the plurality of polishing liquid supply ports 414 are arranged along the radial direction of the polishing pad 100 also in the second state 460. Accordingly, the embodiment allows improving a uniformity of a polishing liquid supply range when the polishing liquid is supplied while moving the polishing liquid supply head 41 above the polishing pad 100. The following describes the point.

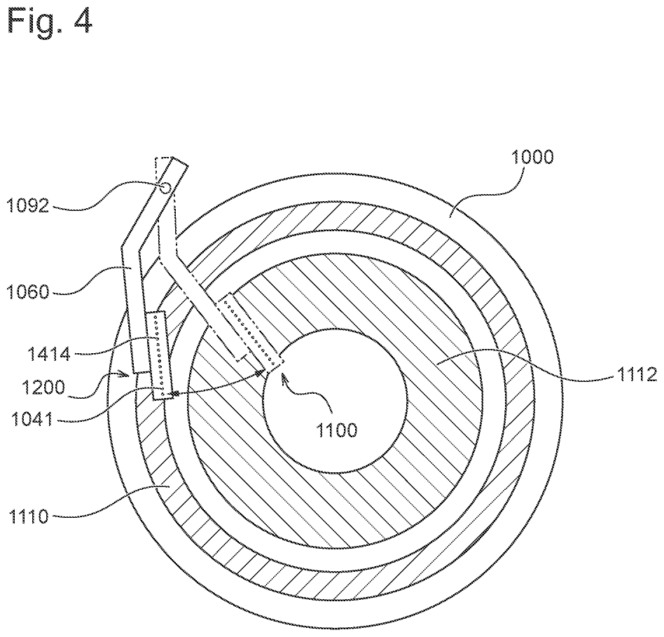

FIG. 4 is a top view illustrating a schematic configuration of a polishing apparatus according to a comparative example. The polishing apparatus of the comparative example includes a polishing liquid supply head 1041 similar to that of the embodiment, an arm 1060 for holding the polishing liquid supply head 1041, a shaft 1092 for rotatably holding the arm 1060, and a rotation mechanism (not illustrated) for rotating the arm 1060 about the shaft 1092. In the polishing apparatus of the comparative example, in a state 1100 where the polishing liquid supply head 1041 is disposed in the center side of a polishing pad 1000, a plurality of polishing liquid supply ports 1414 are arranged along a radial direction of the polishing pad 1000. Therefore, a width in the radial direction of the polishing pad of a polishing liquid supply range 1112 is wide. Meanwhile, in a state 1200 where the arm 1060 is rotated about the shaft 1092 and the polishing liquid supply head 1041 is disposed in an outer edge side of the polishing pad 1000, an arrangement direction of the plurality of polishing liquid supply ports 1414 is shifted from the radial direction of the polishing pad 1000 in a circumferential direction. Therefore, a width in the radial direction of the polishing pad of a polishing liquid supply range 1110 becomes narrow compared with the supply range 1112. As a result, since a slurry supply amount for a predetermined width in radial direction of the substrate WF differs, and it becomes difficult to uniformly supply the polishing liquid to the substrate WF, it becomes difficult to uniformly and efficiently polish the substrate WF.

In contrast, according to the polishing apparatus 1 of the embodiment, the plurality of polishing liquid supply ports 414 are arranged along the radial direction of the polishing pad 100 in both of the first state 450 and the second state 460 in which the polishing liquid supply head 41 is disposed above the polishing pad 100. Accordingly, since the width in the radial direction of the polishing pad of the polishing liquid supply range in the first state 450 becomes approximately equal to the width in the radial direction of the polishing pad of the polishing liquid supply range in the second state 460, the polishing liquid can be uniformly supplied to the substrate WF, and consequently, the substrate WF can be uniformly and efficiently polished.

As indicated by a dashed line 480 in FIG. 3, in the first state 450, a slurry drop position of at least one (that is, innermost polishing liquid supply port) of the plurality of polishing liquid supply ports 414 preferably matches an inner edge of a region brought in contact with the substrate WF on the polishing pad. As indicated by a dashed line 490 in FIG. 3, in the second state 460, a slurry drop position of at least one (that is, outermost polishing liquid supply port) of the plurality of polishing liquid supply ports 414 preferably matches an outer edge of the region brought in contact with the substrate WF on the polishing pad.

According to the polishing apparatus 1 of the embodiment, a damage of the surface to be polished of the substrate WF due to the dust caused by the polishing liquid supply device 40 can be suppressed. That is, in a portion at which two different members (first arm 60-1 and second arm 60-2, second arm 60-2 and shaft 92) are coupled like the first coupling member 60-3 or the second coupling member 60-4, the dust such as an abrasion powder is possibly generated by sliding between the members. When the dust falls on the polishing pad 100, the dust enters between the substrate WF and the polishing pad 100 by the rotation of the polishing table 20, thus possibly damaging the surface to be polished of the substrate WF. In contrast, the first coupling member 60-3 and the second coupling member 60-4 of the embodiment are disposed outside the polishing table 20. Therefore, even when the dust is generated by the sliding between the members in the first coupling member 60-3 or the second coupling member 60-4, the falling on the polishing pad 100 can be suppressed, and consequently, damaging the surface to be polished of the substrate WF can be suppressed.

### (Atomizer)

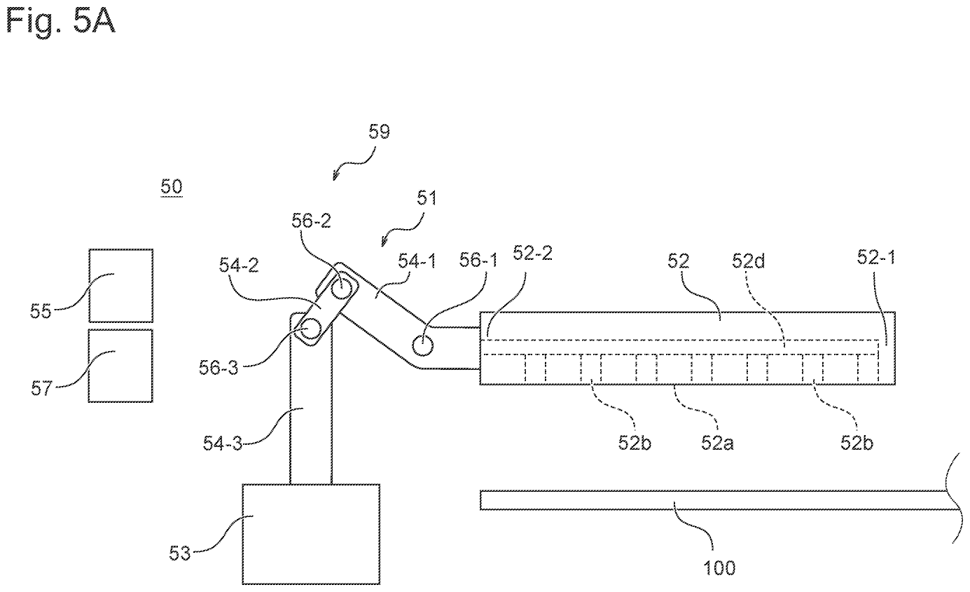

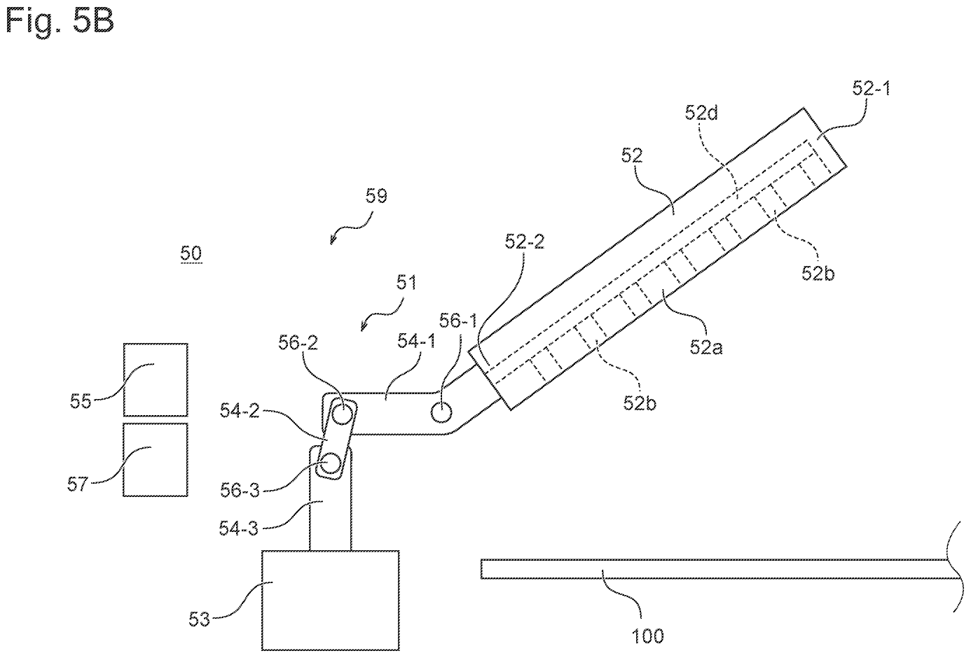

Next, the atomizer 50 of the polishing apparatus 1 in the embodiment will be described. FIG. 5A is a side view illustrating a schematic configuration of an atomizer according to one embodiment, and illustrates a state of the atomizer when supplying a cleaning fluid. FIG. 5B is a side view illustrating the schematic configuration of the atomizer according to the one embodiment, and illustrates a state of the atomizer when not supplying a cleaning fluid.

As illustrated in FIG. 5A and FIG. 5B, the atomizer 50 includes an atomizer main body 52 configured to supply a cleaning fluid to the polishing pad 100. The cleaning fluid is, for example, a mixture fluid of a pure water and a gas (for example, N2). The atomizer main body 52 is a rectangular plate-shaped member disposed to be opposed to the polishing pad 100. The atomizer main body 52 is provided with a flow passage 52d extending from a base end 52-2 to a proximity of a distal end 52-1 of the atomizer main body 52. The atomizer 50 includes a fluid source 55 for supplying the cleaning fluid to the atomizer main body 52. The fluid source 55 is connected to the flow passage 52d. The atomizer main body 52 is provided with a plurality of holes 52b to cause a bottom surface 52a of the atomizer main body 52 to be communicated with the flow passage 52d. The plurality of holes 52b are formed to be spaced at predetermined intervals along a longitudinal direction of the atomizer main body 52. The atomizer main body 52 is configured to supply the cleaning fluid to the polishing pad 100 via the flow passage 52d and the plurality of holes 52b.

The atomizer 50 includes an inclination mechanism 59 for inclining the atomizer main body 52 such that the distal end 52-1 becomes higher than the base end 52-2 of the atomizer main body 52. The inclination mechanism 59 includes a link mechanism 51 connected to the atomizer main body 52, and a drive mechanism 53 for inclining the atomizer main body 52 by driving the link mechanism 51.

Specifically, the link mechanism 51 includes a first link member 54-1, a second link member 54-2 coupled to the first link member 54-1, and a third link member 54-3 coupled to the second link member 54-2. The first link member 54-1 is a rod-shaped member including a bent portion. The first link member 54-1 is supported at the bent portion by a first rotation shaft 56-1 extending in a direction horizontally perpendicular to the longitudinal direction of the atomizer main body 52. The first rotation shaft 56-1 is supported by a bearing (not illustrated), and its position is fixed. This allows the first link member 54-1 to turn about the first rotation shaft 56-1. A first end portion of the first link member 54-1 is coupled to the base end 52-2 of the atomizer main body 52, and a second end portion in the opposite side across the first rotation shaft 56-1 is coupled to the second link member 54-2 via a second rotation shaft 56-2.

The second link member 54-2 has a first end portion coupled to the first link member 54-1 via the second rotation shaft 56-2, and a second end portion coupled to the third link member 54-3 via a third rotation shaft 56-3. The third link member 54-3 is a rod-shaped member extending in the vertical direction, and has a first end portion coupled to the second link member 54-2 via the third rotation shaft 56-3 and a second end portion coupled to the drive mechanism 53.

The drive mechanism 53 is configured to move up and down the third link member 54-3. The drive mechanism 53 can be achieved by a known mechanism, such as a motor or a cylinder. As illustrated in FIG. 5A, when supplying the cleaning fluid to the polishing pad 100, the atomizer main body 52 extends in the horizontal direction. In other words, when supplying the cleaning fluid to the polishing pad 100, the atomizer main body 52 has the distal end 52-1 and the base end 52-2 at approximately the same height. Here, when the atomizer 50 is in the state illustrated in FIG. 5A, moving the polishing liquid supply head 41 above the polishing pad 100 brings the atomizer main body 52 into contact with the polishing liquid supply head 41 in some cases. In view of this, as illustrated in FIG. 5B, the atomizer 50 of the embodiment is configured to incline the atomizer main body 52 by lifting the distal end 52-1 such that the distal end 52-1 becomes higher than the base end 52-2 of the atomizer main body 52 when not supplying the cleaning fluid to the polishing pad 100.

That is, when supplying the cleaning fluid ends, the drive mechanism 53 moves down the third link member 54-3 as illustrated in FIG. 5B. In association with this, since the second link member 54-2 moves down, the second end portion of the first link member 54-1 is pressed down. Consequently, the first link member 54-1 rotates about the first rotation shaft 56-1, and the first end portion of the first link member 54-1 moves up, thereby lifting the distal end 52-1 of the atomizer main body 52. Accordingly, since a space for disposing the polishing liquid supply head 41 is generated below the distal end 52-1 of the atomizer main body 52, the contact of the atomizer main body 52 with the polishing liquid supply head 41 can be avoided.

In a case where the atomizer main body 52 is disposed above the polishing pad 100 as illustrated in FIG. 5B when a cleaning process using the cleaning fluid is not performed, it is not desired that the cleaning fluid drops from the atomizer main body 52 to the polishing pad 100 and is mixed in the polishing liquid during a subsequent polishing process. In view of this, the atomizer 50 of the embodiment includes a gas supply source 57 for performing a purging by injecting a gas (for example, N2) to the flow passage 52d and the plurality of holes 52b of the atomizer main body 52. The gas supply source 57 is configured to perform the purging by injecting the gas to the flow passage 52d and the plurality of holes 52b before lifting the distal end 52-1 of the atomizer main body 52 after the end of the cleaning process using the cleaning fluid. Accordingly, the cleaning fluid dropping to the polishing pad 100 and mixing in the polishing liquid during the polishing process can be suppressed.

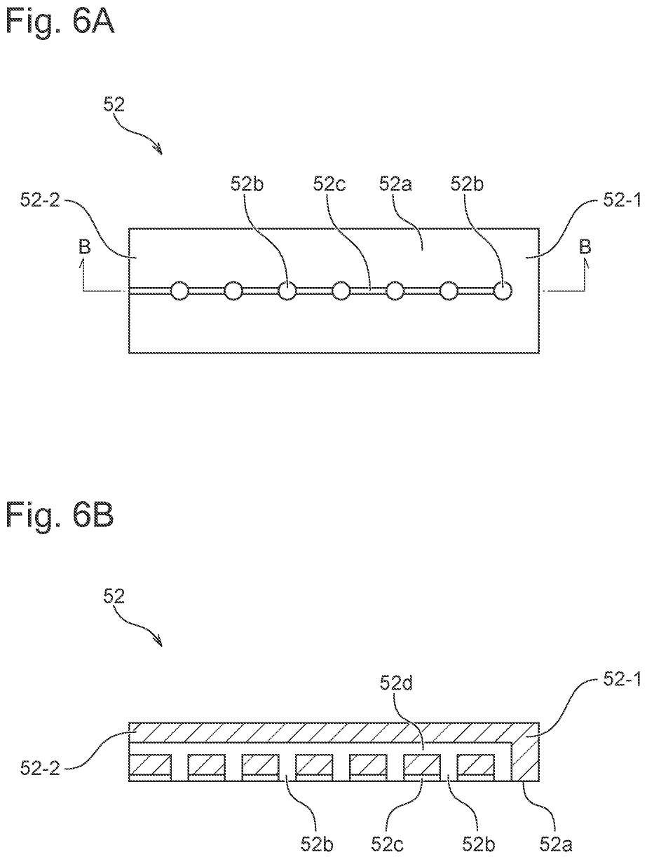

In addition, the atomizer 50 of the embodiment employs a structure in which the cleaning fluid is less likely to drop from the atomizer main body 52. FIG. 6A is a bottom view illustrating a schematic configuration of an atomizer according to one embodiment. FIG. 6B is a cross-sectional view of the atomizer taken along a line B-B of FIG. 6A. As illustrated in FIG. 6A and FIG. 6B, the bottom surface 52a of the atomizer main body 52 is provided with a groove 52c that causes the plurality of holes 52b to be mutually communicated and to be communicated with the base end 52-2 of the atomizer main body 52.

In the state where the distal end 52-1 of the atomizer main body 52 is lifted, the groove 52c can guide the cleaning fluid remaining in the plurality of holes 52b to the base end 52-2 of the atomizer main body 52 and drop the cleaning fluid outside the polishing table 20. Accordingly, according to the atomizer 50 of the embodiment, the cleaning fluid dropping to the polishing pad 100 and mixing in the polishing liquid during the polishing process can be suppressed.

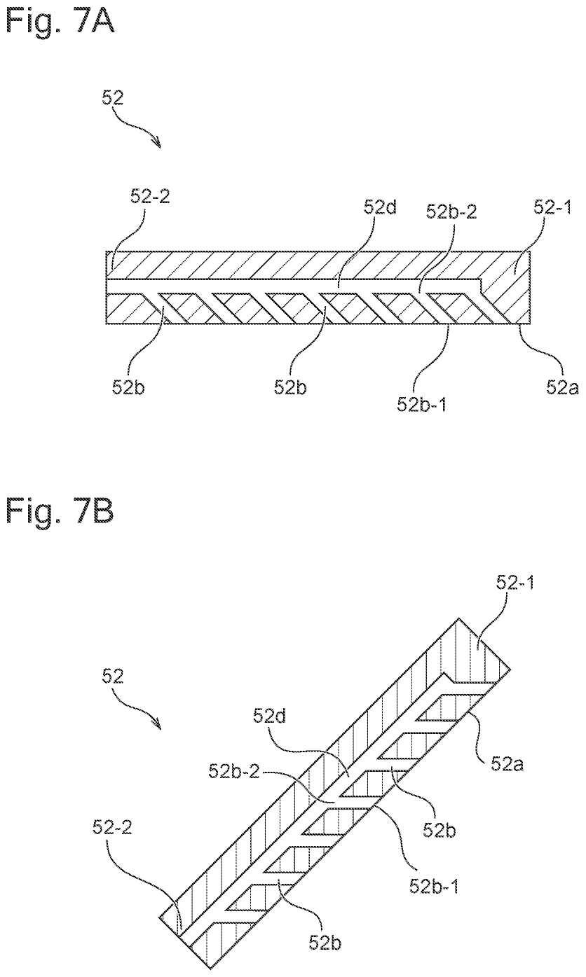

While the atomizer main body 52 in which the plurality of holes 52b are formed to be perpendicular to the bottom surface 52a is described in the embodiment, the configuration is not limited to this. FIG. 7A is a cross-sectional view illustrating a schematic configuration of an atomizer according to a modification. FIG. 7B is a cross-sectional view illustrating the schematic configuration of the atomizer according to the modification. FIG. 7A and FIG. 7B illustrate the cross-sectional surfaces the same as that of FIG. 6B. As illustrated in FIG. 7A and FIG. 7B, the plurality of holes 52b are formed to cause the bottom surface 52a of the atomizer main body 52 to be communicated with the flow passage 52d formed in the atomizer main body 52. Here, the plurality of holes 52b are formed to be inclined such that openings 52b-2 to the flow passage 52d are positioned in the base end 52-2 side with respect to openings 52b-1 to the bottom surface 52a. The plurality of holes 52b are formed so as to linearly connect the openings 52b-1 of the bottom surface 52a and the openings 52b-2 of the flow passage 52d.

According to the atomizer 50 of the modification, in a state where the distal end 52-1 of the atomizer main body 52 is lifted as illustrated in FIG. 7B, the plurality of holes 52b extend in the approximately horizontal direction. Therefore, since the cleaning fluid remaining in the plurality of holes 52b is less likely to drop, the cleaning fluid dropping to the polishing pad 100 and mixing in the polishing liquid during the polishing process can be suppressed.

While the example in which the link mechanism 60 includes two arms and two coupling members is described in the embodiment, the configuration is not limited to this. For example, the link mechanism 60 may include three or more arms and three or more coupling members. This allows fine adjustments of the position and the angle of the polishing liquid supply head 41. While the example in which the polishing liquid supply head 41 is moved in a plane along the polishing surface 102 of the polishing pad 100 is described in the embodiment, the configuration is not limited to this, and the link mechanism 60 may be configured to three-dimensionally move the polishing liquid supply head 41. This allows avoiding an interference of the polishing liquid supply head 41 with another component of the polishing apparatus 1, and allows supplying the polishing liquid to a desired position by the polishing liquid supply head 41 going round while avoiding the interference with the other component of the polishing apparatus 1.

### (Schematic Configuration of Polishing Apparatus)

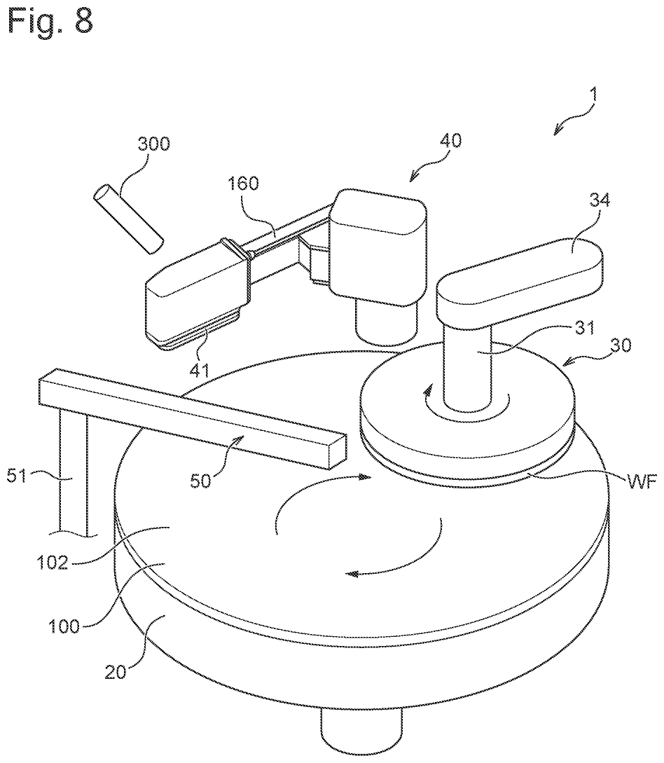

Next, another embodiment of the polishing apparatus will be described. FIG. 8 is a perspective view illustrating a schematic configuration of a polishing apparatus according to one embodiment. A polishing apparatus 1 of the embodiment is configured to polish a circular plate-shaped substrate WF, such as a semiconductor wafer, as an object to be polished by using a polishing pad 100 including a polishing surface 102. As illustrated in the drawing, the polishing apparatus 1 includes a polishing table 20 for supporting the circular plate-shaped polishing pad 100, and a polishing head 30 for holding the substrate WF and pressing the substrate WF against the polishing surface 102 of the polishing pad 100. Furthermore, the polishing apparatus 1 includes a polishing liquid supply device 40 for supplying a polishing liquid (slurry) between the polishing pad 100 and the substrate WF, a cleaning mechanism 300 for supplying a cleaning liquid to the polishing liquid supply device 40 turned to an outside of the polishing pad 100, and an atomizer 50 for injecting a cleaning fluid (a liquid such as a pure water and/or a gas of nitrogen or the like) to the polishing surface 102 and washing away the already used polishing liquid, polishing residues, and the like. The polishing liquid supply device 40 is disposed in an upstream side of the rotation of the polishing pad 100 with respect to the substrate WF. While an example in which the cleaning mechanism 300 is disposed above the polishing liquid supply device 40 is illustrated in the embodiment of FIG. 8, the configuration is not limited thereto, and for example, the polishing liquid supply device 40 may be configured to be cleaned from upper and lower directions by disposing the cleaning mechanisms 300 in respective upper and lower sides of the polishing liquid supply device 40. In this description, the upstream and the downstream mean an upstream and a downstream in a case where the polishing table 20 (polishing pad 100) rotates clockwise when the polishing table 20 (polishing pad 100) is viewed from above in FIG. 8.

Since the polishing table 20, the polishing head 30, and the atomizer 50 of the polishing apparatus 1 in this embodiment are similar to those in the embodiment described with reference to FIG. 1 to FIG. 7, the repeated explanation is omitted.

### (Polishing Liquid Supply Device)

The polishing liquid supply device 40 includes a polishing liquid supply head 41 for supplying the polishing liquid to the polishing pad 100. Since the polishing liquid supply head 41 of the polishing apparatus 1 in this embodiment is similar to that in the embodiment described with reference to FIG. 2, the repeated explanation is omitted.

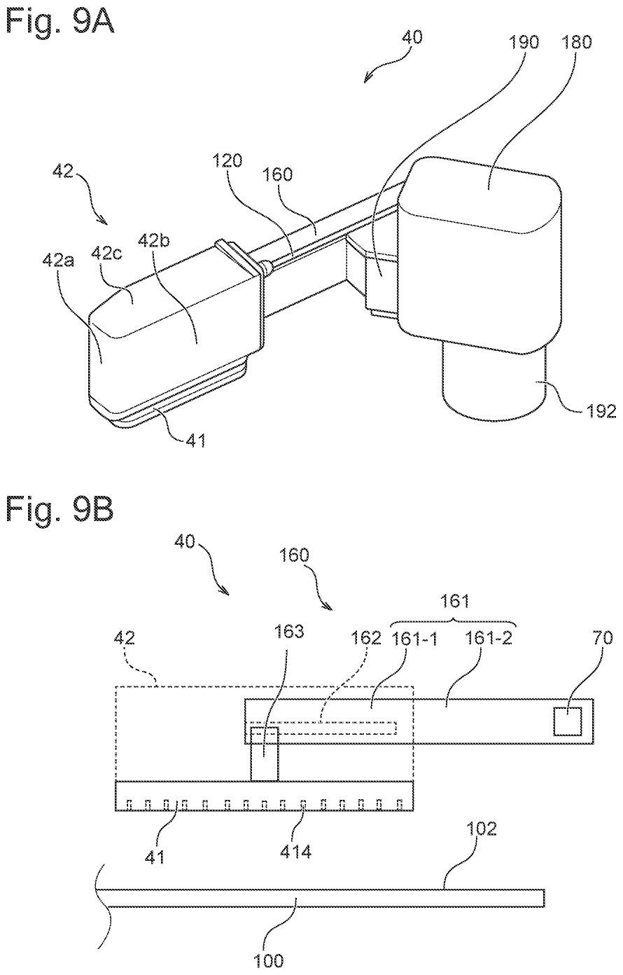

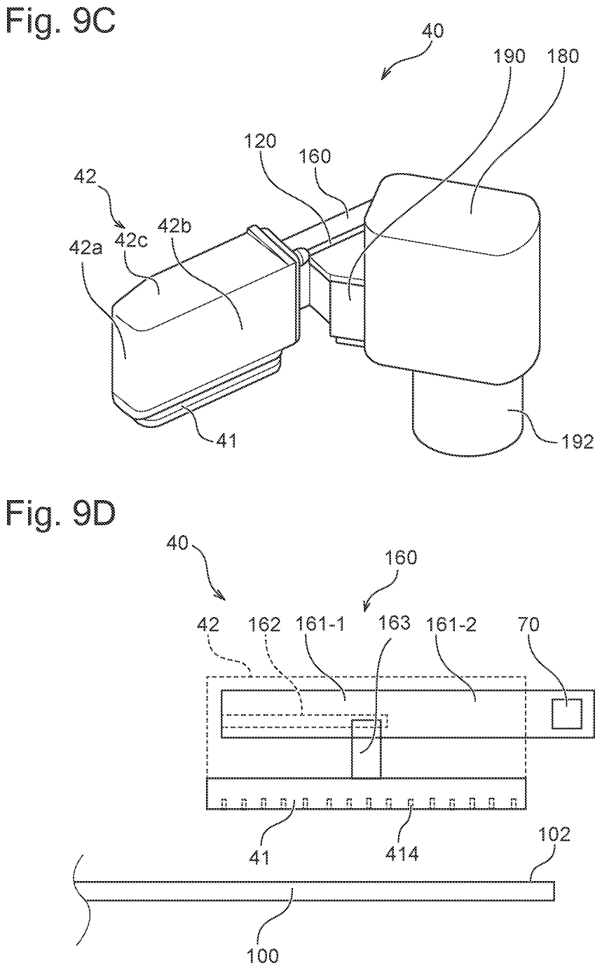

FIG. 9A is a perspective view illustrating a schematic configuration of a polishing liquid supply device according to one embodiment, and illustrates a state where an arm is stretched. FIG. 9B is a side view illustrating the schematic configuration of the polishing liquid supply device according to the one embodiment, and illustrates the state where the arm is stretched. FIG. 9C is a perspective view illustrating the schematic configuration of the polishing liquid supply device according to the one embodiment, and illustrates a state where the arm is shrunk. FIG. 9D is a side view illustrating the schematic configuration of the polishing liquid supply device according to the one embodiment, and illustrates the state where the arm is shrunk.

As illustrated in FIG. 9A to FIG. 9D, the polishing liquid supply device 40 includes an arm 160 configured to hold the polishing liquid supply head 41. The arm 160 is supported by a shaft 192 that is disposed adjacent to the polishing table 20 and extends in the vertical direction such that the arm 160 can rotate about the shaft 192. The arm 160 includes an arm main body 161 configured to extend along the polishing surface 102 of the polishing pad 100, and a connecting member 163 configured to connect an upper surface of the polishing liquid supply head 41 to the arm main body 161. The arm main body 161 extends along the polishing surface 102 of the polishing pad 100 at a position higher than the polishing liquid supply head 41. Specifically, a bottom surface of the arm main body 161 is disposed at a position higher than a bottom surface of the polishing liquid supply head 41.

The polishing liquid supply device 40 includes a rotation mechanism 190 configured to rotate the arm 160 about the shaft 192. The rotation mechanism 190 can be achieved by a known mechanism, such as a motor. The polishing liquid supply device 40 includes an elevating mechanism 180 configured to collectively move up and down the polishing liquid supply head 41, the arm 160, the rotation mechanism 190, and a linear motion drive mechanism 70 described below. The elevating mechanism 180 can be achieved by a known mechanism, such as a cylinder or a motor.

The polishing liquid supply device 40 includes the linear motion drive mechanism 70 configured to linearly move the polishing liquid supply head 41 along a radial direction of the polishing pad 100. Specifically, a groove 162 is formed along the extending direction of the arm main body 161 in a side surface of the arm main body 161, and the connecting member 163 is held to be movable along the groove 162 by the arm main body 161. The linear motion drive mechanism 70 is configured to linearly move the polishing liquid supply head 41 along the radial direction of the polishing pad 100 by moving the connecting member 163 along the groove 162 of the arm main body 161. The linear motion drive mechanism 70 can be achieved by a known mechanism, such as a cylinder or a motor.

In this embodiment, the linear motion drive mechanism 70 is configured to linearly move the polishing liquid supply head 41 such that a plurality of polishing liquid supply ports 414 of the polishing liquid supply head 41 are always arranged along the radial direction of the polishing pad 100 when the polishing liquid is supplied to the polishing pad 100. In other words, the linear motion drive mechanism 70 linearly moves the polishing liquid supply head 41 between the center side and the outer edge side of the polishing pad 100 along the radial direction of the polishing pad 100 in a state where the plurality of polishing liquid supply ports 414 are disposed to be opposed to the polishing pad 100 along the radial direction of the polishing pad 100. In this description, the radial direction of the polishing pad 100 not only strictly means the radial direction of the polishing pad 100, but an angle in a range of 10° is also assumed as the radial direction.

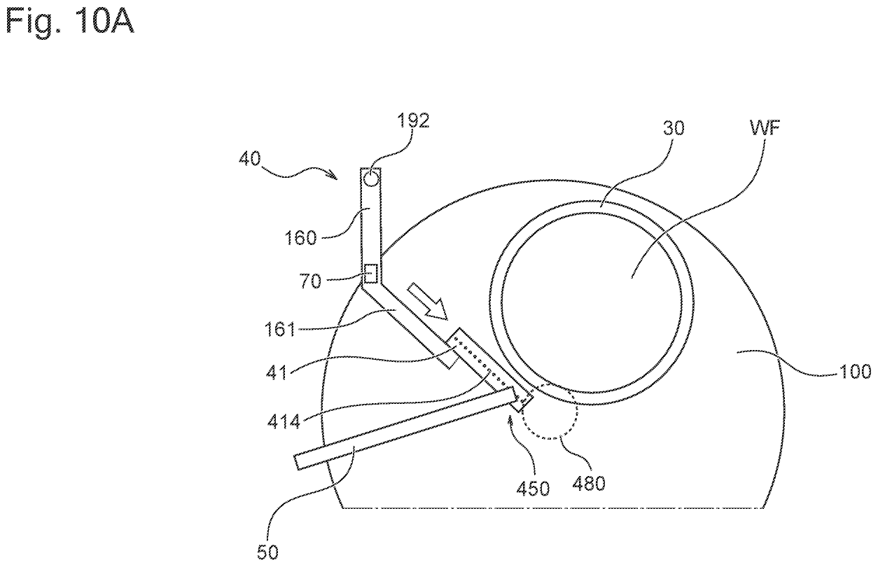

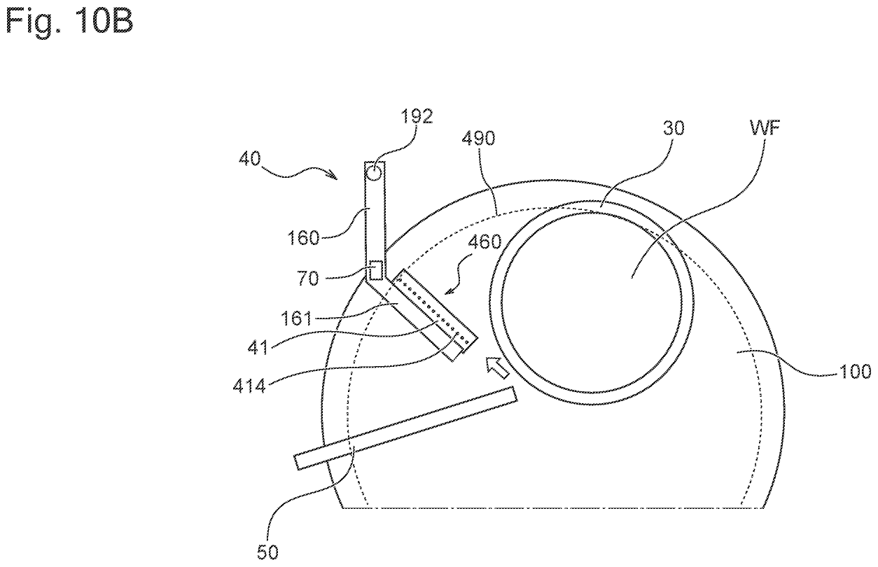

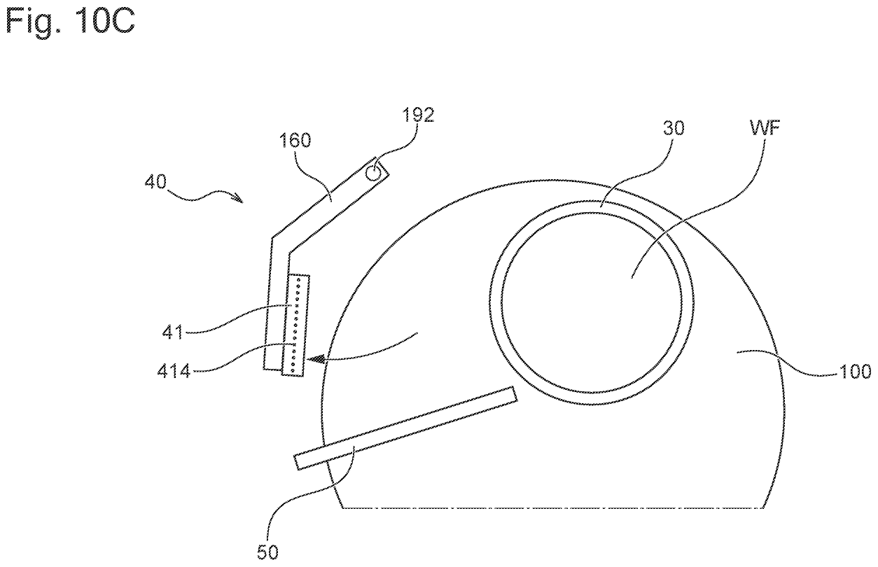

FIG. 10A is a top view illustrating a schematic configuration of a polishing apparatus according to one embodiment, and illustrates a state where a polishing liquid supply head is disposed in a center side of a polishing pad. FIG. 10B is a top view illustrating the schematic configuration of the polishing apparatus according to the one embodiment, and illustrate a state where the polishing liquid supply head is disposed in an outer edge side of the polishing pad. FIG. 10C is a top view illustrating the schematic configuration of the polishing apparatus according to the one embodiment, and illustrate a state where the polishing liquid supply head is disposed outside a polishing table.

As illustrated in FIG. 10A and FIG. 10B, the linear motion drive mechanism 70 linearly moves the polishing liquid supply head 41 along the radial direction of the polishing pad 100 between a first state 450 in which the polishing liquid supply head 41 is disposed to be opposed to the center side of the polishing pad 100 and a second state 460 in which the polishing liquid supply head 41 is disposed to be opposed to the outer edge side of the polishing pad 100 compared with the first state 450. The plurality of polishing liquid supply ports 414 are arranged along the radial direction of the polishing pad 100 in the first state 450, and the plurality of polishing liquid supply ports 414 are arranged along the radial direction of the polishing pad 100 also in the second state 460. Accordingly, the embodiment allows improving a uniformity of a polishing liquid supply range to the polishing pad 100 when the polishing liquid is supplied while moving the polishing liquid supply head 41 above the polishing pad 100. The following describes the point.

In the polishing apparatus of the comparative example illustrated in FIG. 4, in a state 1100 where the polishing liquid supply head 1041 is disposed in the center side of a polishing pad 1000, a plurality of polishing liquid supply ports 1414 are arranged along a radial direction of the polishing pad 1000. Therefore, a width in the radial direction of the polishing pad of a polishing liquid supply range 1112 is wide. Meanwhile, in a state 1200 where the arm 1060 is rotated about the shaft 1092 and the polishing liquid supply head 1041 is disposed in an outer edge side of the polishing pad 1000, an arrangement direction of the plurality of polishing liquid supply ports 1414 is shifted from the radial direction of the polishing pad 1000 in a circumferential direction. Therefore, a width in the radial direction of the polishing pad of a polishing liquid supply range 1110 becomes narrow compared with the supply range 1112. As a result, since a slurry supply amount for a predetermined width in radial direction of the substrate WF differs, and it becomes difficult to uniformly supply the polishing liquid to the substrate WF, it becomes difficult to uniformly and efficiently polish the substrate WF.

In contrast, according to the polishing apparatus 1 of the embodiment, the plurality of polishing liquid supply ports 414 are arranged along the radial direction of the polishing pad 100 in both of the first state 450 and the second state 460 in which the polishing liquid supply head 41 is disposed above the polishing pad 100. Accordingly, since the width in the radial direction of the polishing pad of the polishing liquid supply range in the first state 450 becomes approximately equal to the width in the radial direction of the polishing pad of the polishing liquid supply range in the second state 460, the polishing liquid can be uniformly supplied to the substrate WF, and consequently, the substrate WF can be uniformly and efficiently polished.

As indicated by a dashed line 480 in FIG. 10A, in the first state 450, a slurry drop position of at least one (that is, innermost polishing liquid supply port) of the plurality of polishing liquid supply ports 414 preferably matches an inner edge of a region brought in contact with the substrate WF on the polishing pad. As indicated by a dashed line 490 in FIG. 10B, in the second state 460, a slurry drop position of at least one (that is, outermost polishing liquid supply port) of the plurality of polishing liquid supply ports 414 preferably matches an outer edge of the region brought in contact with the substrate WF on the polishing pad.

As illustrated in FIG. 10A, the linear motion drive mechanism 70 linearly moves the polishing liquid supply head 41 such that a distal end of the polishing liquid supply head 41 is disposed at a position farther from the shaft 192 than a distal end of the arm main body 161 in the first state 450. Accordingly, even when a length of the arm main body 161 is short, the polishing liquid can be supplied to the center of the polishing pad 100. In addition, as illustrated in FIG. 10C, the rotation mechanism 190 retreats the polishing liquid supply head 41 to the outside of the polishing table 20 by rotating the arm 160 in the second state 460 where the polishing liquid supply head 41 is disposed in the outer edge side of the polishing pad 100. By rotating the arm 160 in a state where the polishing liquid supply head 41 is moved to the position close to the shaft 192, it can be avoided that the polishing liquid supply head 41 collides with a structure, such as the atomizer 50, above the polishing table or around the polishing table when the polishing liquid supply head 41 is retreated to the outside of the polishing table 20. As illustrated in FIG. 10A to FIG. 10C, since the arm main body 161 includes a bent portion, the arm 160 and the polishing liquid supply head 41 can be rotated with small rotation radii, and consequently, the collision of the arm 160 and the polishing liquid supply head 41 with a peripheral component, such as the atomizer 50, can be avoided.

In this embodiment, the arm main body 161 is disposed at a position higher than the polishing liquid supply head 41. Accordingly, even when the polishing liquid supplied from the polishing liquid supply head 41 to the polishing pad 100 collides with the polishing surface 102 and is scattered on the polishing pad 100, the polishing liquid is less likely to adhere to the arm main body 161. Provisionally, when the polishing liquid adheres to the arm main body 161, the polishing liquid may drop from the arm main body 161 to an unintended position on the polishing pad 100, or the polishing liquid adhered to the arm main body 161 may dry and become a dust, and then the dust may fall to the polishing pad 100, and consequently, an unevenness in a polishing profile and a defect factor of the substrate WF are possibly caused. In contrast, according to the embodiment, since the adhesion of the polishing liquid bouncing from the polishing pad 100 to the arm main body 161 can be suppressed, the unevenness in the polishing profile of the substrate WF and the occurrence of the defect on the substrate WF caused by the polishing liquid bouncing from the polishing pad 100 can be suppressed.

As illustrated in FIG. 9A to FIG. 9D, the polishing liquid supply device 40 includes a cover 42 for covering an upper surface of the polishing liquid supply head 41 and the arm main body 161. The cover 42 includes a front wall 42a extending upward from the distal end of polishing liquid supply head 41, side walls 42b extending upward from both side portions of the polishing liquid supply head 41, and an upper wall 42c connecting top portions of the front wall 42a and the side walls 42b. The upper surface of the polishing liquid supply head 41 and the arm main body 161 are covered with the front wall 42a, the side walls 42b, and the upper wall 42c.

The cover 42 is attached to the polishing liquid supply head 41. Accordingly, the cover 42 is configured to be movable along the arm main body 161 in association with the linear motion of the polishing liquid supply head 41. As illustrated in FIG. 9A and FIG. 9B, the cover 42 covers the upper surface of the polishing liquid supply head 41 and a first part 161-1 including the distal end of the arm main body 161 when the polishing liquid supply head 41 is disposed in the center side of the polishing pad 100. Meanwhile, as illustrated in FIG. 9C and FIG. 9D, the cover 42 is configured to cover the upper surface of the polishing liquid supply head 41, the first part 161-1 of the arm main body 161, and a second part 161-2 in the base end side with respect to the first part 161-1 of the arm main body 161 when the polishing liquid supply head 41 is disposed in the outer edge side of the polishing pad 100.

Accordingly, according to the polishing apparatus 1 of the embodiment, since the upper surface of the polishing liquid supply head 41 and the arm main body 161 in a region where the polishing liquid easily scatters immediately above the plurality of polishing liquid supply ports 414 is covered with the cover 42, the adhesion of the polishing liquid bouncing from the polishing pad 100 can be suppressed. The adhesion of the polishing liquid to the upper surface of the polishing liquid supply head 41 and the arm main body 161 is not desired because the adhered polishing liquid dries and becomes the dust, drops on the polishing pad 100, and possibly causes the unevenness in the polishing profile and the defect factor of the substrate WF. In this respect, when the polishing liquid adheres to the upper surface of the polishing liquid supply head 41 and the arm main body 161, it is considered to clean the polishing liquid supply head 41 and the arm main body 161 by using a cleaning mechanism 300 in a state where the polishing liquid supply head 41 is retreated to the outside of the polishing table 20 as illustrated in FIG. 10C. However, since the polishing liquid supply head 41 and the arm main body 161 include components having shapes with depressions or the like, and further, gaps are generated in connecting portions between a plurality of components, the polishing liquid entering the depressions or the gaps possibly fails to be sufficiently cleaned. In contrast, since the surface of the cover 42 is flat and smooth, when the polishing liquid adheres to the cover 42, a cleaning process is performed in a state where the polishing liquid supply head 41 is retreated to the outside of the polishing table 20, thereby allowing washing away the polishing liquid adhered to the cover 42.

While the example in which the polishing liquid is supplied to the whole surface of the substrate WF by moving the polishing liquid supply head 41 in a fixed range between the dashed line 480 and the dashed line 490 is described for the polishing apparatus 1 described with reference to FIG. 1 to FIG. 10, the configuration is not limited to this. The polishing apparatus 1 can move the polishing liquid supply head 41 in any range. For example, when it is intended to supply the polishing liquid intensively to a predetermined region of the substrate WF in the proximity of the center of the polishing pad 100, the polishing apparatus 1 can move the polishing liquid supply head 41 in a range of the proximity of the dashed line 480. Thus, the polishing apparatus 1 can supply the polishing liquid in a desired distribution corresponding to the types or the like of the substrate WF and the polishing liquid.

While the example in which the polishing liquid supply head 41 is moved at a constant speed is described for the polishing apparatus 1 described with reference to FIG. 1 to FIG. 10, the configuration is not limited to this. For example, in the polishing apparatus 1, the moving range of the polishing liquid supply head 41 can be divided into a plurality of areas, and the moving speed of the polishing liquid supply head 41 can be differed for each area. The polishing apparatus 1 can supply the polishing liquid in a desired distribution by, for example, increasing the moving speed of the polishing liquid supply head 41 to reduce the supply amount of the polishing liquid in the center side of the polishing pad 100, and decreasing the moving speed of the polishing liquid supply head 41 to increase the supply amount of the polishing liquid in the outer edge side of the polishing pad 100.

While some embodiments of the present invention have been described above, the above-described embodiments of the invention are for ease of understanding the present invention, and are not for limiting the present invention. It is obvious that the present invention can be changed or improved without departing from its gist, and that the present invention encompasses its equivalents. Within a range that can solve at least a part of the above-described problems or a range that provides at least a part of the effects, any combination or omission of each component described in the claim and the description are allowed.

This application discloses a polishing apparatus that includes: a table for supporting a polishing pad; a polishing head for holding an object: and a polishing liquid supply device for supplying a polishing liquid between the polishing pad and the object. The polishing apparatus polishes the object by bringing the polishing pad into contact with the object in a presence of a polishing liquid and rotationally moving the polishing pad and the object with respect to one another. The polishing liquid supply device includes a polishing liquid supply head including a plurality of polishing liquid supply ports, a link mechanism configured to move the polishing liquid supply head along a polishing surface of the polishing pad, and a drive mechanism configured to drive the link mechanism. The drive mechanism is configured to drive the link mechanism such that the plurality of polishing liquid supply ports are arranged along a radial direction of the polishing pad in a first state where the polishing liquid supply head is disposed to be opposed to a center side of the polishing pad and the plurality of polishing liquid supply ports are arranged along a radial direction of the polishing pad in a second state where the polishing liquid supply head is disposed to be opposed to an outer edge side of the polishing pad compared with the first state, as one embodiment.

Furthermore, this application discloses a polishing apparatus in which the link mechanism includes a first arm configured to hold the polishing liquid supply head and a second arm coupled to the first arm, the drive mechanism includes a first rotation mechanism for rotating the first arm so as to turn the polishing liquid supply head along the polishing surface of the polishing pad, and a second rotation mechanism for rotating the second arm so as to turn the first arm, and the first rotation mechanism and the second rotation mechanism are configured to rotate the first arm and the second arm such that the plurality of polishing liquid supply ports are arranged along the radial direction of the polishing pad in the first state and the plurality of polishing liquid supply ports are arranged along the radial direction of the polishing pad in the second state, as one embodiment.

Furthermore, this application discloses a polishing apparatus further includes a shaft disposed adjacent to the table and extending in a vertical direction. The link mechanism further includes a first coupling member configured to rotatably couple the first arm to the second arm, and a second coupling member configured to rotatably couple the second arm to the shaft, and the first coupling member and the second coupling member are disposed in an outside of the table, as one embodiment.

Furthermore, this application discloses a polishing apparatus in which the drive mechanism is configured to drive the link mechanism such that the polishing liquid supply head moves between the first state, the second state, and a third state where the polishing liquid supply head is disposed in the outside of the table, as one embodiment.

This application discloses a polishing apparatus that includes: a table for supporting a polishing pad; a polishing head for holding an object: and a polishing liquid supply device for supplying a polishing liquid between the polishing pad and the object. The polishing apparatus polishes the object by bringing the polishing pad into contact with the object in a presence of a polishing liquid and rotationally moving the polishing pad and the object with respect to one another. The polishing liquid supply device includes a polishing liquid supply head including a plurality of polishing liquid supply ports, an arm that extends along a polishing surface of the polishing pad at a position higher than the polishing liquid supply head and is configured to hold the polishing liquid supply head, and a linear motion drive mechanism configured to linearly move the polishing liquid supply head between a center side and an outer edge side of the polishing pad along a radial direction of the polishing pad in a state where the plurality of polishing liquid supply ports are arranged to be opposed to the polishing pad along the radial direction of the polishing pad, as one embodiment.

This application discloses a polishing apparatus in which the arm includes an arm main body extending along the polishing surface of the polishing pad, and a connecting member configured to connect an upper surface of the polishing liquid supply head and the arm main body, the linear motion drive mechanism is configured to linearly move the polishing liquid supply head along the radial direction of the polishing pad by moving the connecting member along the arm main body, and a bottom surface of the arm main body is disposed at a position higher than a bottom surface of the polishing liquid supply head, as one embodiment.

This application discloses a polishing apparatus in which the polishing liquid supply device further includes: a shaft disposed adjacent to the table and extending in a vertical direction; and a rotation mechanism configured to rotate the arm about the shaft, and the linear motion drive mechanism linearly moves the polishing liquid supply head such that a distal end of the polishing liquid supply head is disposed at a position farther from the shaft than a distal end of the arm when the polishing liquid supply head is disposed in the center side of the polishing pad, as one embodiment.

This application discloses a polishing apparatus in which the polishing liquid supply device further includes a cover for covering the upper surface of the polishing liquid supply head and the arm main body, and the cover is attached to the polishing liquid supply head, and configured to be movable along the arm main body in association with the linear motion of the polishing liquid supply head, and the cover is configured to cover the upper surface of the polishing liquid supply head and a first part including a distal end of the arm main body when the polishing liquid supply head is disposed in the center side of the polishing pad, and cover the upper surface of the polishing liquid supply head, the first part of the arm main body, and a second part in a base end side with respect to the first part of the arm main body when the polishing liquid supply head is disposed in an outer edge side of the polishing pad, as one embodiment.

This application discloses a polishing apparatus further includes an atomizer configured to supply a cleaning fluid to the polishing pad. The atomizer includes an atomizer main body disposed to be opposed to the polishing pad, and an inclination mechanism for inclining the atomizer main body such that a distal end of the atomizer main body becomes higher than a base end of the atomizer main body, as one embodiment.

This application discloses a polishing apparatus in which the inclination mechanism includes a link mechanism connected to the atomizer main body, and a drive mechanism for inclining the atomizer main body by driving the link mechanism, as one embodiment.

This application discloses a polishing apparatus in which the atomizer main body includes a flow passage extending from the base end to a proximity of the distal end of the atomizer main body, and is provided with a plurality of holes through which a bottom surface of the atomizer main body is communicated with the flow passage, and the bottom surface of the atomizer main body is provided with a groove through which the plurality of holes are mutually communicated and communicated with the base end of the atomizer main body, as one embodiment.

### REFERENCE SIGNS LIST

1 . . . polishing apparatus
20 . . . polishing table
30 . . . polishing head
40 . . . polishing liquid supply device
41 . . . polishing liquid supply head
42 . . . cover
51 . . . link mechanism
52 . . . atomizer main body
52-1 . . . distal end
52-2 . . . base end
52a . . . bottom surface
52b . . . hole
52c . . . groove
52d . . . flow passage
53 . . . drive mechanism
59 . . . inclination mechanism
60 . . . link mechanism
60-1 . . . first arm
60-2 . . . second arm
60-3 . . . first coupling member
60-4 . . . second coupling member
61 . . . connecting member
80 . . . elevating mechanism
90 . . . drive mechanism
90-1 . . . first rotation mechanism
90-2 . . . second rotation mechanism
92 . . . shaft
100 . . . polishing pad
160 . . . arm
161 . . . arm main body
161-1 . . . first part
161-2 . . . second part
162 . . . groove
163 . . . connecting member
410 . . . supply member main body
414 . . . polishing liquid supply port
450 . . . first state
460 . . . second state
470 . . . third state
WF . . . substrate

What is claimed is:

1. A polishing apparatus comprising:
a table for supporting a polishing pad;
a polishing head for holding an object: and
a polishing liquid supply device for supplying a polishing liquid between the polishing pad and the object, wherein
the polishing apparatus is configured to polish the object by bringing the polishing pad into contact with the object in a presence of a polishing liquid and rotationally moving the polishing pad and the object with respect to one another,
the polishing liquid supply device includes: a polishing liquid supply head including a plurality of polishing liquid supply ports; a link mechanism configured to move the polishing liquid supply head along a polishing surface of the polishing pad; and a drive mechanism configured to drive the link mechanism; and
the drive mechanism is configured to drive the link mechanism such that the plurality of polishing liquid supply ports are arranged along a radial direction of the polishing pad in a first state where the polishing liquid supply head is disposed to be opposed to a center side of the polishing pad, and the plurality of polishing liquid supply ports are arranged along a radial direction of the polishing pad in a second state where the polishing liquid supply head is disposed to be opposed to an outer edge side of the polishing pad compared with the first state.

2. The polishing apparatus according to claim 1, wherein
the link mechanism includes a first arm configured to hold the polishing liquid supply head and a second arm coupled to the first arm,
the drive mechanism includes a first rotation mechanism for rotating the first arm so as to turn the polishing liquid supply head along the polishing surface of the polishing pad, and a second rotation mechanism for rotating the second arm so as to turn the first arm, and
the first rotation mechanism and the second rotation mechanism are configured to rotate the first arm and the second arm such that the plurality of polishing liquid supply ports are arranged along the radial direction of the polishing pad in the first state, and the plurality of polishing liquid supply ports are arranged along the radial direction of the polishing pad in the second state.

3. The polishing apparatus according to claim 2, further comprising
a shaft disposed adjacent to the table and extending in a vertical direction, wherein
the link mechanism further includes a first coupling member configured to rotatably couple the first arm to the second arm, and a second coupling member configured to rotatably couple the second arm to the shaft, and
the first coupling member and the second coupling member are disposed in an outside of the table.

4. The polishing apparatus according to claim 3, wherein
the drive mechanism is configured to drive the link mechanism such that the polishing liquid supply head moves between the first state, the second state, and a third state where the polishing liquid supply head is disposed in the outside of the table.

5. A polishing apparatus comprising:
a table for supporting a polishing pad;
a polishing head for holding an object: and
a polishing liquid supply device for supplying a polishing liquid between the polishing pad and the object, wherein
the polishing apparatus is configured to polish the object by bringing the polishing pad into contact with the object in a presence of a polishing liquid and rotationally moving the polishing pad and the object with respect to one another, and
the polishing liquid supply device includes: a polishing liquid supply head including a plurality of polishing liquid supply ports; an arm that extends along a polishing surface of the polishing pad at a position higher than the polishing liquid supply head and is configured to hold the polishing liquid supply head; and a linear motion drive mechanism configured to linearly move the polishing liquid supply head between a center side and an outer edge side of the polishing pad along a radial direction of the polishing pad in a state where the plurality of polishing liquid supply ports are arranged to be opposed to the polishing pad along the radial direction of the polishing pad.

6. The polishing apparatus according to claim 5, wherein
the arm includes an arm main body extending along the polishing surface of the polishing pad, and a connecting member configured to connect an upper surface of the polishing liquid supply head and the arm main body,
the linear motion drive mechanism is configured to linearly move the polishing liquid supply head along the radial direction of the polishing pad by moving the connecting member along the arm main body, and
a bottom surface of the arm main body is disposed at a position higher than a bottom surface of the polishing liquid supply head.

7. The polishing apparatus according to claim 6, wherein
the polishing liquid supply device further includes:
a shaft disposed adjacent to the table and extending in a vertical direction; and
a rotation mechanism configured to rotate the arm about the shaft; and
the linear motion drive mechanism is configured to linearly move the polishing liquid supply head such that a distal end of the polishing liquid supply head is disposed at a position farther from the shaft than a distal end of the arm when the polishing liquid supply head is disposed in the center side of the polishing pad.

8. The polishing apparatus according to claim 7, wherein
the polishing liquid supply device further includes a cover for covering the upper surface of the polishing liquid supply head and the arm main body, and
the cover is attached to the polishing liquid supply head, and configured to be movable along the arm main body in association with the linear motion of the polishing liquid supply head, and the cover is configured to cover the upper surface of the polishing liquid supply head and a first part including a distal end of the arm main body when the polishing liquid supply head is disposed in the center side of the polishing pad, and cover the upper surface of the polishing liquid supply head, the first part of the arm main body, and a second part in a base end side with respect to the first part of the arm main body when the polishing liquid supply head is disposed in an outer edge side of the polishing pad.

9. The polishing apparatus according to claim 1, further comprising
an atomizer configured to supply a cleaning fluid to the polishing pad, wherein
the atomizer includes an atomizer main body disposed to be opposed to the polishing pad, and an inclination mechanism for inclining the atomizer main body such that a distal end of the atomizer main body becomes higher than a base end of the atomizer main body.

10. The polishing apparatus according to claim 9, wherein
the inclination mechanism includes a link mechanism connected to the atomizer main body, and a drive mechanism for inclining the atomizer main body by driving the link mechanism.

11. The polishing apparatus according to claim 10, wherein
the atomizer main body includes a flow passage extending from the base end to a proximity of the distal end of the atomizer main body, and is provided with a plurality of holes through which a bottom surface of the atomizer main body is communicated with the flow passage, and
the bottom surface of the atomizer main body is provided with a groove through which the plurality of holes are mutually communicated and communicated with the base end of the atomizer main body.
